(19) United States
(12) Patent Application Publication
(10) Pub. No.: US 2006/0273425 A1
(43) Pub. Date: Dec. 7, 2006

(54) High density capacitor structure

(76) Inventors: Qadeer A. Khan, New Delhi (IN); Kulbhushan Misri, Haryana (IN)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/403,392

(22) Filed: Apr. 13, 2006

(30) Foreign Application Priority Data
Jun. 6, 2005 (IN) 1457/DEL/2005

(51) Int. Cl. H01L 29/00

(52) U.S. Cl. 257/532

(57) ABSTRACT

A capacitor structure for an integrated circuit having at least first, second and third layers, with each layer having first and second conductors, includes multiple sidewall capacitors formed between sidewalls of the first conductor and the second conductor in each layer. Several inter-layer capacitors are formed between the first and second conductors in the first and second layers. Further, via capacitors are formed between sidewalls of adjacent vias corresponding to different conductors. The vias are formed between the second and third layers.

### BACKGROUND OF THE INVENTION

The present invention relates generally to integrated circuits and, in particular, to capacitors in integrated circuits.

Capacitor structures such as gate capacitors, p-n junction capacitors, metal-insulator-metal (MIM) capacitors, and fringe capacitors are commonly used in integrated circuits.

MIM capacitors and fringe capacitors are parallel plate capacitors formed by two conductors separated by a dielectric. An MIM capacitor has a dielectric layer sandwiched between two conductors in two different metal layers of the integrated circuit. Fringe capacitors are formed in a metal layer by sidewalls of two different conductors separated by a narrow gap. MIM capacitors and fringe capacitors have an advantage over gate capacitors and p-n junction capacitors in that their capacitances are independent of applied voltages. However, typical capacitance densities of MIM capacitors and fringe capacitors are not sufficient hence consume large area on the silicon.

Conventional approaches for increasing capacitance densities include decreasing dielectric layer thickness, and using dielectric layers having high dielectric constants. However, these approaches do not significantly increase the capacitance density and are not very cost effective as they require additional processing step.

### BRIEF DESCRIPTION OF THE DRAWINGS

The following detailed description of preferred embodiments of the invention will be better understood when read in conjunction with the appended drawings. The present invention is illustrated by way of example and not limited by the accompanying figures, in which like references indicate similar elements.

FIG. 1 is a schematic block diagram of a capacitor structure in accordance with an embodiment of the present invention; and

FIG. 2 depicts exemplary interleaved patterns of conductors in accordance with an embodiment of the present invention.

### DETAILED DESCRIPTION OF THE INVENTION

The detailed description in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention.

The present invention provides a capacitor structure for an integrated circuit. The integrated circuit includes at least a first layer, a second layer, and a third layer. Each layer comprises a first conductor and a second conductor. The capacitor structure includes a plurality of sidewall capacitors between sidewalls of the first conductor and the second conductor in each layer. A plurality of inter-layer capacitors are formed between the first conductor and the second conductor placed in the first layer and the second layer. Further, at least one via capacitor is formed between sidewalls of at least one first via and at least one second via. The at least one first via is between the first conductor in the second layer and the first conductor in the third layer. The at least one second via is between the second conductor in the second layer and the second conductor in the third layer.

In another embodiment of the present invention, a capacitor structure for an integrated circuit is provided. The integrated circuit includes at least first, second, third and fourth metal layers. Each layer has first and second conductors. The capacitor structure includes a plurality of sidewall capacitors formed between sidewalls of the first and second conductors in each of the first, second, third and fourth layer. A plurality of inter-layer capacitors is formed between the first and second conductors that are placed in the first layer and the second layer, and in the third layer and the fourth layer. Further, there is at least one via capacitor formed between sidewalls of at least one first via and at least one second via. The at least one first via is formed between the first conductor in the second layer and the first conductor in the third layer. The at least one second via is formed between the second conductor in the second layer and the second conductor in the third layer.

The capacitor structure of the present invention has a high capacitance per unit area and can be implemented using any standard Complementary Metal Oxide semiconductor (CMOS) technology. Further, the implementation does not require additional processing steps.

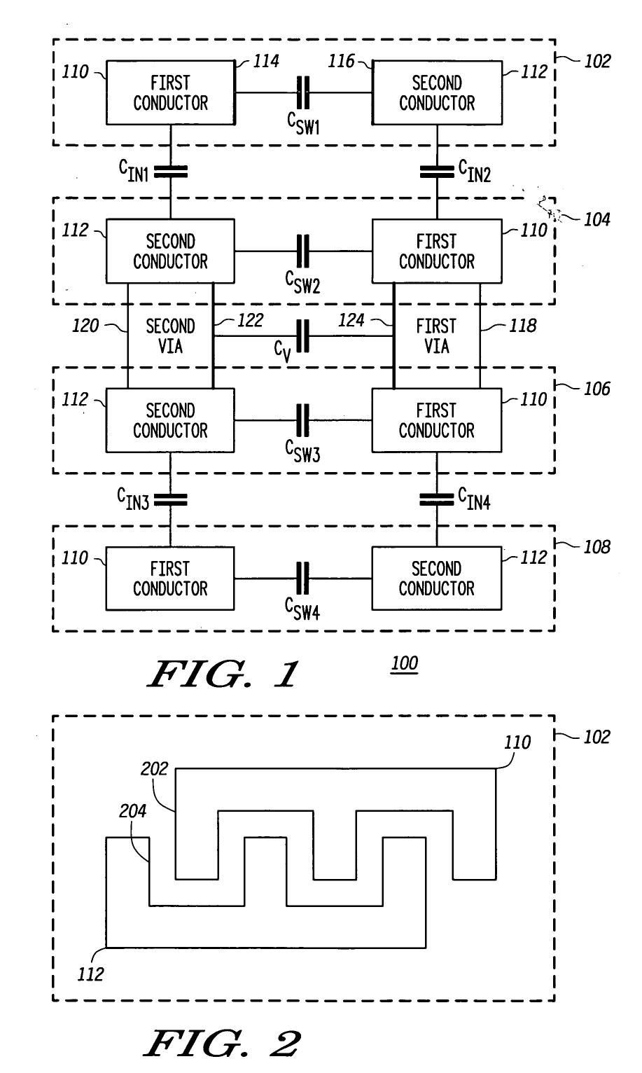

FIG. 1 is a schematic block diagram of a capacitor structure 100 in an integrated circuit in accordance with an embodiment of the present invention. The integrated circuit includes at least a first layer 102, a second layer 104, a third layer 106, and a fourth layer 108. Each of the first, second, third, and fourth layers 102, 104, 106 and 108 are electrically isolated one from another with a dielectric layer. More particularly, dielectric layers lie between the first layer 102 and the second layer 104, the second layer 104 and the third layer 106, and between the third layer 106 and the fourth layer 108. Each of the first, second, third, and fourth layers 102, 104, 106 and 108 includes a first conductor 110 and a second conductor 112. The first and second conductors 110 and 112 preferably are formed of strips of metal that are located in each layer such that sidewalls of the first conductor 110 are generally parallel to neighboring sidewalls of the second conductor 112. The sidewalls of two neighboring conductors form parallel plate capacitors. For example, a sidewall 114 of the first conductor 110 forms a capacitor having a capacitance C_{sw1} with a sidewall 116 of the second conductor 112 in the first layer 102. In an embodiment of the present invention, the two sidewalls 114, 116 are separated by a dielectric. It is to be noted that a capacitance is associated with each layer due to formation of sidewall capacitors in each of the layers. Thus, the first layer 102 has a sidewall capacitor with capacitance C_{sw1}, the second layer 104 has a sidewall capacitor with capacitance C_{sw2}, the third layer 106 has a sidewall capacitor with capacitance C_{sw3}, and the fourth layer 108 has a sidewall capacitor with capacitance C_{sw4}.

In an embodiment of the present invention, the metal strips of the first conductor 110 form an interleaved pattern in each of the first, second, third and fourth layers 102, 104, 106 and 108. Similarly, the metal strips of the second conductor 112 also form an interleaved pattern in each of the first, second, third and fourth layers 102, 104, 106 and 108. For example, both the first conductor 110 and the second conductor 112 form interleaved patterns in the first layer 102.

FIG. 2 depicts exemplary interleaved patterns of the first conductor 110 and the second conductor 112 in the first layer 102 in accordance with an embodiment of the present invention. The first conductor 110 and the second conductor 112 are interleaved in such a manner that their sidewalls form parallel plate capacitors. For example, a sidewall 202 of the first conductor 110 is generally parallel to a sidewall 204 of the second conductor 112. The two sidewalls 202 and 204 form a parallel plate capacitor. It will be noted by those of skill in the art that several such sidewall capacitors are formed by the interleaved conductors 110 and 112.

Referring back to FIG. 1, the second conductor 112 in the second layer 104 is placed just below the first conductor 110 in the first layer 102. Similarly, the first conductor 110 in the second layer 104 is placed just below the second conductor 112 in the first layer 102. Since the first layer 102 is separated from the second layer 104 by a dielectric layer, the second conductor 112 in the second layer 104 forms a first inter-layer capacitor Cᵢₙ₁ with the first conductor 110 in the first layer 102. Similarly, the first conductor 110 in the second layer 104 forms a second inter-layer capacitor Cᵢₙ₂ with the second conductor 112 in the first layer 102.

Similar to the first and second inter-layer capacitors Cᵢₙ₁ and Cᵢₙ₂ formed between the first and second layers 102 and 104, third and fourth inter-layer capacitors Cᵢₙ₃ and Cᵢₙ₄ are formed between the third and fourth layers 106 and 108 because the first conductor 110 in the fourth layer 108 is placed just below the second conductor 112 in the third layer 106, and the second conductor 112 in the fourth layer 108 is placed just below the first conductor 110 in the third layer 106.

The capacitor structure 100 further includes at least one via capacitor Cᵥ. In one embodiment, a first via 118 is formed between the first conductor 110 in the second layer 104 and the first conductor 110 in the third layer 106. Similarly, a second via 120 is present between the second conductor 112 in the second layer 104 and the second conductor 112 in the third layer 106. In an embodiment of the present invention, both of the fist and second vias 118 and 120 are made of metal. A sidewall 122 of the first via 118 and a sidewall 124 of the second via 120 are separated by a dielectric and thus form the via capacitor Cᵥ.

The total capacitance of the capacitor structure 100 is given by,
C=C_{sw1}+Csw₂+C_{sw3}+C_{sw4}+Cᵢₙ₁+Cᵢₙ₂+Cᵢₙ₃+Cᵢₙ₄+Cᵥ (1)
It is to be noted that the capacitor structure 100 has a higher capacitance density than a capacitor structure having only sidewall capacitors, or inter-layer capacitors.

Comparing the present invention to a circuit in which a combination of fringe capacitors and via capacitors are used (hereinafter referred to as CKT1), putting vias between successive metal layers may provide high capacitance density, but due to the fact that via shape is highly unpredictable due to process capabilities and variations, the capacitance varies greatly with process, which makes such a circuit (CKT1) unsuitable for applications where high precision capacitors are required.

Comparing the present invention to a circuit in which a combination of fringe capacitors and inter-metal capacitors are used (hereinafter referred to as CKT2), using only metal-metal sandwich capacitors and fringe capacitors by rearranging the metal layers, provides a more precise capacitance value because the circuit has lower variation across process. Unfortunately, capacitor density is less than ideal due to the presence of thick inter-metal oxide.

The present invention comprises a composite capacitor that includes both via and inter-metal capacitors along with fringe capacitors. The capacitor of the present invention has a lower variation across process and a higher capacitance density as compared to presently known fringe capacitors. For example, if ΔCm is a variation due to process in the inter-metal capacitor, ΔCf is the variation due to process in the metal fringe capacitor and ΔCv is the variation due to process in the via-via capacitor, then usually ΔCv>ΔCf, ΔCm. Hence total variation in a fringe capacitor like CKT1 will be excessively large. If we assume Cp1 is the total cap variation in CKT1, Cp2 is total cap variation in CKT2, then the variation in the present invention Cp is: Cp1>Cp>Cp2, and the cap densities will be: Cd1>Cd>Cd2; where, Cd1 is the cap density per unit area of CKT1; Cd2 is the cap density per unit area of CKT2; and Cd is the cap density per unit area of the proposed invention. Depending upon the application, the number of via-via capacitors and metal-metal capacitors can be adjusted. For example, if high precision is required, then less via-via capacitors and more metal-metal capacitors are used. On the other hand, more via-via capacitors are used if higher density is required. A capacitor with the same number of via-via capacitors and metal-metal capacitors provides very high precision and density.

While various embodiments of the invention have been illustrated and described, it will be clear that the invention is not limited to these embodiments only. For example, if the integrated circuit has only three layers, than a capacitor structure having a total capacitance give by
C=C_{sw1}+C_{sw2}+C_{sw3}+Cᵢₙ₁+Cᵢₙ₂+Cᵥ (2)
is formed. Numerous modifications, changes, variations, substitutions, and equivalents will be apparent to those skilled in the art, without departing from the spirit and scope of the invention, as described in the claims.

1. A capacitor structure for an integrated circuit, the integrated circuit including at least first, second and third layers, each layer having first and second conductors, the capacitor structure comprising:
a plurality of sidewall capacitors between sidewalls of the first and second conductors in each layer;
a plurality of inter-layer capacitors between the first conductor and the second conductor placed in the first layer and the second layer; and
at least one via capacitor between sidewalls of at least one first via and at least one second via, wherein the at least one first via is between the first conductor in the second layer and the first conductor in the third layer, and the at least one second via is between the second conductor in the second layer and the second conductor in the third layer.

2. The capacitor structure of claim 1, wherein each layer is electrically isolated from other layers.

3. The capacitor structure of claim 1, wherein a dielectric is used between the sidewalls of the at least one first via and the at least one second via.

4. The capacitor structure of claim 1, wherein a dielectric is used between the sidewalls of the first conductor and the second conductor.

5. The capacitor structure of claim 1, wherein a dielectric is used between the first conductor and the second conductor.

6. The capacitor structure of claim 1, wherein the at least one first via is formed of a metal.

7. The capacitor structure of claim 1, wherein the at least one second via is formed of a metal.

8. The capacitor structure of claim 1, wherein the first conductor comprises at least one first metal strip, and the second conductor comprises at least one second metal strip.

9. The capacitor structure of claim 8, wherein the at least one first metal strip forms an interleaved pattern in each layer.

10. The capacitor structure of claim 9, wherein the at least one second metal strip forms an interleaved pattern in each layer.

11. The capacitor structure of claim 8, wherein the at least one first metal strip is parallel to the at least one second metal strip in each layer.

12. The capacitor structure of claim 1, wherein the integrated circuit includes a fourth layer having the first and second conductors, wherein the plurality of sidewall capacitors includes sidewall capacitors between sidewalls of the first and second conductors of the fourth layer, and the plurality of inter-layer capacitors includes inter-layer capacitors between the first and second conductors in the third and fourth layers.

13. A capacitor structure for an integrated circuit, the integrated circuit including at least first, second, third and fourth metal layers, each layer having first and second conductors, the capacitor structure comprising:
a plurality of sidewall capacitors formed between sidewalls of the first and second conductors in each of the first, second, third and fourth layer;
a plurality of inter-layer capacitors formed between the first and second conductors placed in the first layer and the second layer, and in the third layer and the fourth layer; and
at least one via capacitor between sidewalls of at least one first via and at least one second via, wherein the at least one first via is formed between the first conductor in the second layer and the first conductor in the third layer, and the at least one second via is formed between the second conductor in the second layer and the second conductor in the third layer.

14. The capacitor structure of claim 13, wherein each layer is electrically isolated from other layers.

15. The capacitor structure of claim 13, wherein a dielectric is used between the sidewalls of the first and second vias.
